(19) United States
(12) Patent Application Publication
(10) Pub. No.: US 2008/0006933 A1
(43) Pub. Date: Jan. 10, 2008

(54) Heat-dissipating package structure and fabrication method thereof

(75) Inventors: Chien-Ping Huang, Hsinchu Hsein (TW); Ho-Yi Tsai, Taichung Hsien (TW); Wen Tsung Tseng, Taichung (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/704,599

(22) Filed: Feb. 8, 2007

(30) Foreign Application Priority Data
Jul. 4, 2006 (TW) 095124258

(51) Int. Cl. H01L 23/34; H01L 21/00

(52) U.S. Cl. 257/712; 438/122; 257/E23.08; 257/E21.001

(57) ABSTRACT

The invention provides a heat-dissipating package structure and a fabrication method thereof. The fabrication method includes the steps of mounting and electrically connecting a semiconductor chip to a chip carrier; mounting on the semiconductor chip a heat-dissipating member having an interface layer; performing a molding process to form an encapsulant that encapsulates the semiconductor chip and the heat-dissipating member; cutting the chip carrier and the encapsulant according to a predetermined package size and forming an oblique angle on a top edge of the encapsulant to partially expose an edge of the heat-dissipating member; and removing the encapsulant located on the interface layer. During the molding process, the formed encapsulant can cover the interface layer due to a spacing height exists between the interface layer and the top wall of the mold cavity, thereby preventing damages to the semiconductor chip pressed by the mold and the problem of flash.

### BACKGROUND OF THE INVENTION

1. Field of the Invention

The present invention relates generally to a heat-dissipating package structure and the fabrication method thereof, and more particularly to a semiconductor package structure having a heat-dissipating member and the fabrication method thereof.

2. Description of Related Art

In compliance with the demands for the miniaturization of electronic products, semiconductor chip packages integrated with high-density electronic components and circuits have become mainstream products. However, such integrated packages generate a great amount of heat during operation. If the accumulated heat is not dissipated efficiently in a timely fashion, the electrical performance of semiconductor chips and the product stability can be seriously affected. Meanwhile, in order to prevent internal circuits of a semiconductor package from contamination, the surface of a semiconductor chip is generally encapsulated by an encapuslant for insulation. As the encapuslant is usually made of a material having low heat conductivity at about only 0.8 w/mK, the heat-dissipating efficiency of the semiconductor package is decreased Therefore, a heat-dissipating member is usually disposed inside of a semiconductor package in order to increase the heat-dissipating efficiency.

Referring to FIG. 1, a semiconductor package 1 disclosed by U.S. Pat. No. 5,726,079 is shown, in which a heat sink 11 is directly attached to a chip 10 with the top surface thereof exposed from an encapsulant 12 encapsulating the chip 10. Thereby, the heat generated by the chip 10 can be dissipated to the atmosphere through the heat sink 11 without having to pass through the encapsulant 12 having poor heat conductivity.

However, the semiconductor package 1 has some inherent drawbacks. First, to perform a molding process to form the encapsulant 12 after the heat sink 11 is attached to the chip 10, the top surface 11a of the heat sink 11 must directly abut against the top wall of the mold cavity. Otherwise, the encapsulant may flash onto the top surface 11a of the heat sink 11 and adversely affect the heat-dissipating efficiency of the heat sink 11 and the product appearance. As a result, a deflash process is needed for removing the encapsulant flashed onto the top surface 11a of the heat sink 11, not only increasing the time and the cost for fabrication, but also may lead to damages to the fabricated product. On the other hand, the chip 10 can be easily damaged if too strong a pressure is applied in order to abut the top surface 11a of the heat sink 11 against the top wall of the mold cavity. In addition, to make the distance from the top surface 11a of the heat sink 11 to the upper surface of the substrate 13 precisely equal to the depth of the mold cavity, the attachment of the heat sink 11 to the chip 10, the attachment from the chip 10 to the substrate 13, and the thickness of the heat sink 11 all need to be precisely controlled and fabricated, thereby increasing complexity and difficulty in fabrication.

Accordingly, U.S. Pat. No. 6,458,626 and U.S. Pat. No. 6,444,498 respectively disclose semiconductor packages to overcome the problems mentioned above by directly attaching the heat sink to the chip without causing damage to the chip or the problem of exposing the heat sink on the surface of the package due to the flash of the encapsulant, as shown in FIGS. 2A to 2C and FIG. 3. In FIG. 2A, an interface layer 25 is formed on one surface of a heat sink 21 to be exposed to the atmosphere. The adhesion between the interface layer 25 and the encapsulant 24 can be stronger or weaker than that between the interface layer 25 and the heat sink 21. Then, the heat sink 21 is directly mounted on a chip 20 of a substrate 23. Subsequently, a molding process is performed so as to form an encapsulant 24 encapsulating the chip 20, the heat sink 21 and the interface layer 25 of the heat sink 21. Thus, the depth of the mold cavity can be larger than the total thickness of the chip 20 and the heat sink 21. Therefore, after engaging the mold the mold does not contact the heat sink 21 and that prevents the chip 20 from damage. Then, as shown in FIGS. 2B and 2C, a cutting process is performed and the encapsulant 24 located on the heat sink 21 is removed. Therein, if the adhesion between the interface layer 25 such as a gold plated layer and the heat sink 21 is larger than that between the interface layer 25 and the encapsulant 24, the encapsulant 24 can be thoroughly removed through the removing process while the interface layer 25 remains on the heat sink 21 but not the encapsulant to avoid the flash of the encapsulant On the other hand, if the adhesion between the interface layer 25 such as a P.I. tape and the encapsulant 24 is larger than that between the interface layer 25 and the heat sink 21, both the encapsulant 24 and the interface layer 25 can be removed through the removing process, as shown in FIG. 3, which also overcomes the conventional flash problem. However, during the above cutting process, cutting tools need to continuously pass through the heat sink generally made of a metal material such as copper and aluminum, if a cutting tool is used to cut the heat sink, rough edges or burrs can be formed on the periphery of the heat sink, thereby adversely affecting the product appearance and causing wearing of the cutting tool.

Therefore, there exists a need for an improved heat-dissipating package structure and fabrication method thereof that can overcome the above problems.

### SUMMARY OF THE INVENTION

In view of the above drawbacks, an objective of the present invention is to provide a heat-dissipating package structure and the fabrication method thereof, which can prevent the semiconductor chip from damage caused by mold pressure during the molding process and prevent the flash problem, thereby increasing the product yield.

Another objective of the present invention is to provide a heat-dissipating package structure and the fabrication method thereof, through which the problem of burrs and wearing the cutting tools can be prevented so as to reduce the cost.

In order to attain the above and other objectives, the present invention proposes a method for fabricating a heat-dissipating package structure, comprising the steps of: mounting and electrically connecting at least a semiconductor chip to a chip carrier; mounting a heat-dissipating member on the semiconductor chip, wherein the heat-dissipating member has an interface layer on the surface thereof; performing a molding process s to form an encapsulant that encapsulates both the semiconductor chip and the heat-dissipating member having the interface layer; cutting the chip carrier and the circumference of the encapsulant according to a predetermined package size; forming an oblique angle on the top edge of the encapsulant to partially expose the edge of the heat-dissipating member having the interface layer; and performing a removing process for removing the encapsulant located on the interface layer of the heat-dissipating member.

The material of the interface layer can be a P.I (polyimide) tape, an epoxy resin or an organic layer that makes the adhesion between the interface layer and the encapsulant larger than that between the interface layer and the heat-dissipating member. Thus, both the interface layer and the encapsulant located on the interface layer can be removed through the removing process so as to expose the surface of the heat-dissipating member, thereby conducting the heat generated by the semiconductor chip to the outside. Alternatively, the interface layer can be selected as a metal layer made of such as Au or Ni for making the adhesion between the interface layer and the heat-dissipating member larger than that between the interface layer and the encapsulant. Thus, when the encapsulant located on the interface layer is removed through the removing process, the interface layer remains on the heat-dissipating member and exposes from the encapsulant. The heat generated by the semiconductor chip can be dissipated to the outside through the heat-dissipating member and the interface layer.

Through the above fabrication method, the present invention also discloses a heat-dissipating package structure, comprising: a chip carrier; a semiconductor chip mounted and electrically connected to the chip carrier; a heat-dissipating member mounted on the semiconductor chip; and an encapsulant formed on the chip carrier for encapsulating the semiconductor chip and the heat-dissipating member, an oblique angle being formed on the top edge of the encapsulant surrounding the heat-dissipating member and the upper surface of the heat-dissipating member being exposed from the encapsulant.

The chip carrier can be a BGA substrate or an LGA substrate.

The semiconductor chip can be electrically connected to the chip carrier through a flip chip method or a wire bonding method. If the semiconductor chip is electrically connected to the chip carrier through a flip chip method, the heat-dissipating member having the interface layer can be mounted directly on the non-active surface of the semiconductor chip. On the other hand, if the semiconductor chip is electrically connected to the chip carrier through a wire bonding method, a supporting object is first disposed on the active surface of the semiconductor chip without affecting the bonding wire and then the heat-dissipating member having the interface layer is mounted on the supporting object, thereby preventing the heat-dissipating member from contacting the bonding wires, and meanwhile effectively dissipating the heat generated by the semiconductor chip. The supporting object can be a scraped chip or a heat-dissipating member.

Accordingly, the heat-dissipating package structure and the fabrication method thereof mainly comprise the steps of: mounting and electrically connecting a semiconductor chip to a chip carrier; mounting a heat-dissipating member having an interface layer on the semiconductor chip; forming an encapsulant that encapsulates the semiconductor chip and the heat-dissipating member having the interface layer on the chip carrier; subsequently, cutting the chip carrier and the encapsulant according to a predetermined package size and forming an oblique angle on the top edge of the encapsulant to partially expose the edge of the heat-dissipating member having the interface layer; and removing the encapsulant located on the interface layer of the heat-dissipating member, thereby forming a heat-dissipating package structure. During the molding process, as a spacing height exists between the interface layer and the top wall of the mold cavity, the formed encapsulant can cover the interface layer, thereby preventing damages to the semiconductor chip due to the pressure of the mold as well as the flash of the encapsulant. Meanwhile, since only the encapsulant and the chip carrier will be cut in the cutting process but not the heat-dissipating member, the problem of burrs and wearing of cutting tools can be prevented to thereby reduce the cutting cost.

### BRIEF DESCRIPTION OF DRAWINGS

FIG. 1 is a sectional diagram of a semiconductor package disclosed by U.S. Pat. No. 5,726,079;

FIGS. 2A to 2C are sectional diagrams of a semiconductor package disclosed by U.S. Pat. No. 6,458,626;

FIG. 3 is a sectional diagram of a semiconductor package disclosed by U.S. Pat. No. 6,444,498;

FIGS. 4A to 4F are diagrams showing a heat-dissipating package structure and the fabrication method thereof according to a first embodiment of the present invention;

FIGS. 5A and 5B are diagrams showing a heat-dissipating package structure according to a second embodiment of the present invention;

FIG. 6 is a sectional diagram of a heat-dissipating package structure according to a third embodiment of the present invention; and

FIGS. 7A and 7B are sectional diagrams of a heat-dissipating package structure according to a fourth embodiment of the present invention.

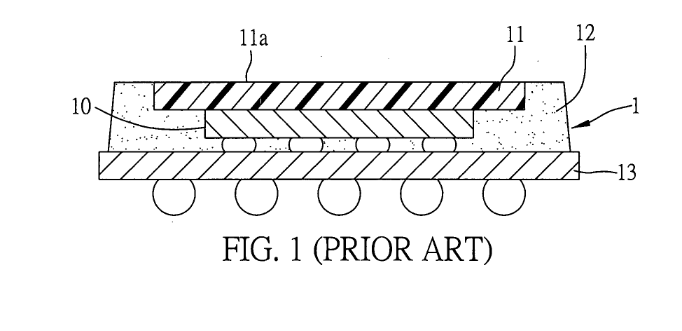

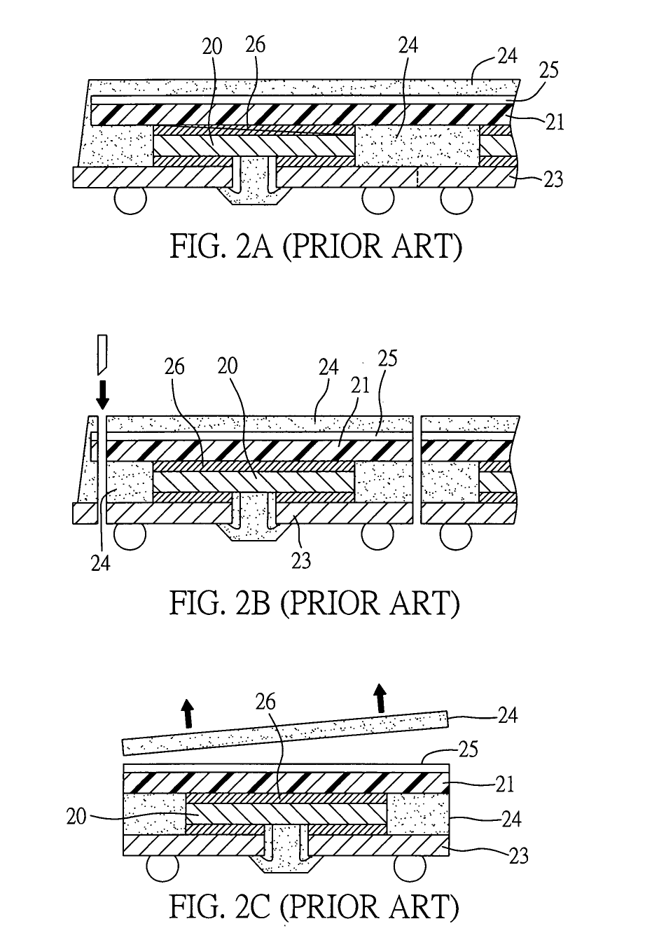

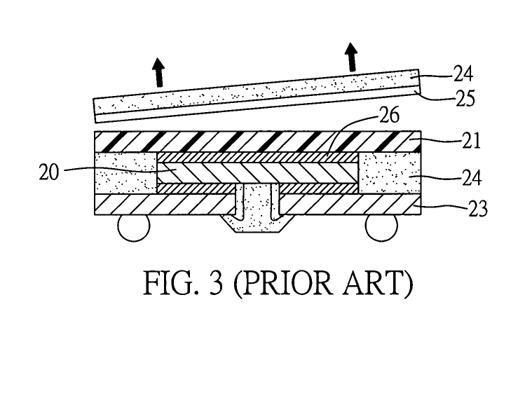

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be made without departing from the spirit of the present invention.

### First Embodiment

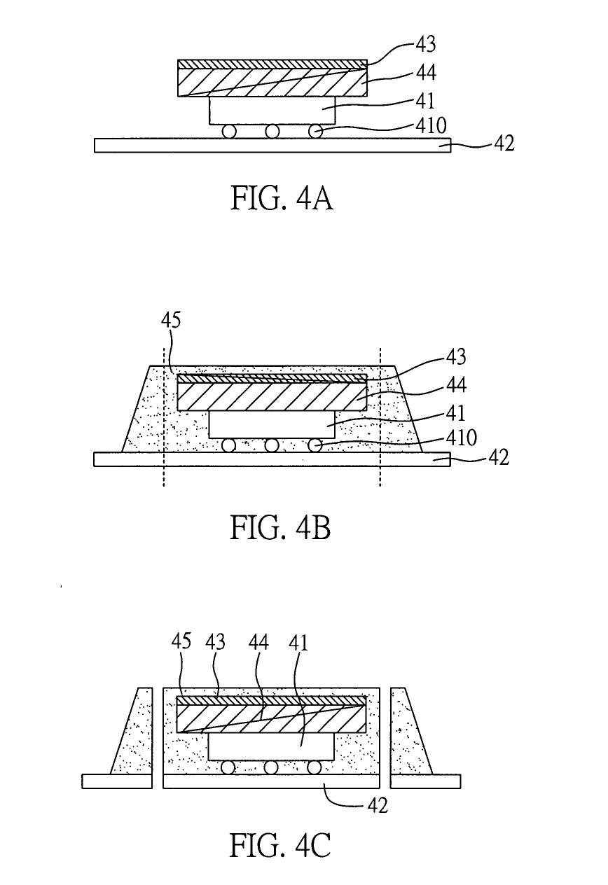

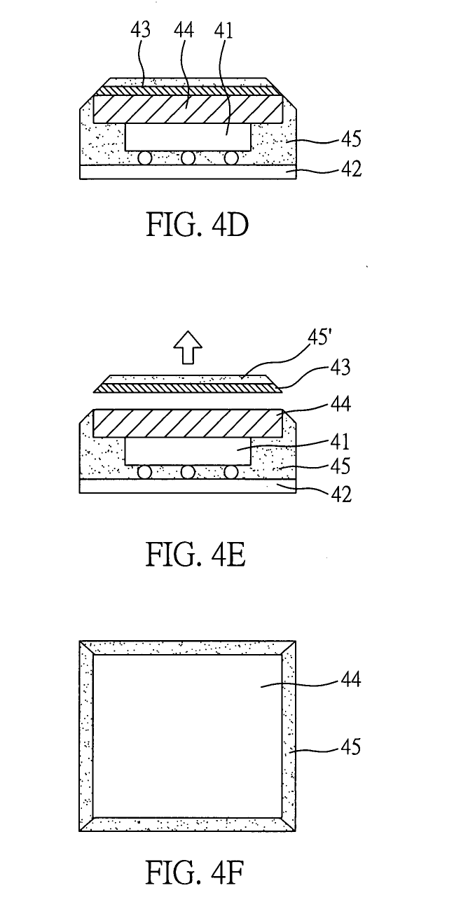

FIGS. 4A to 4F are diagrams showing a heat-dissipating package structure and a fabrication method thereof according to a first embodiment of the present invention.

As shown in FIG. 4A, a semiconductor chip 41 is mounted and electrically connected to a chip carrier 42. A heat-dissipating member 44 having an interface layer 43 on the surface thereof is mounted to the semiconductor chip 41. Therein, the planar size of the heat-dissipating member 41 does not exceed that a predetermined package size to be formed.

The chip carrier 42 may be a BGA substrate or an LGA substrate. The semiconductor chip 41 may be a flip-chip semiconductor chip, the active surface thereof being electrically connected to the chip carrier 42 through a plurality of conductive bumps 410.

The interface layer 43 may be a P.I. tape adhered to the heat-dissipating member 44, an epoxy resin coated on the heat-dissipating member 44, or an organic layer made of such as wax formed on the heat-dissipating member 44. Thus, the adhesion between the interface layer 43 and the encapsulant formed subsequently for encapsulating the semiconductor chip 41 is stronger than that between the interface layer 43 and the heat-dissipating member 44, such that the interface layer and the extra encapsulant located on the interface layer can be removed through a removing process.

As shown in FIG. 4B, the chip carrier 42 with the semiconductor chip 41 and the heat-dissipating member 44 having the interface layer 43 is disposed in a mold cavity (not shown) for performing a subsequent molding process. As a result, an encapsulant 45 encapsulating the heat-dissipating member 44 having the interface layer 43 and the semiconductor chip 41 is formed. As a spacing height exists between the interface layer 43 and the top wall of the mold cavity, the semiconductor chip 41 is prevented from being pressed by the mold after being engaged. In addition, the adhesion between the heat-dissipating member 44 and the semiconductor chip 41 needs not precisely controlled, thereby improving the product yield and the product reliability.

As shown in FIG. 4C, a cutting process is performed to cut the chip carrier 42 and the circumference of the encapsulant 45 according to a predetermined package size. Since the heat-dissipating member 44 will not be cut, the problem of burrs and wearing the cutting tools caused from cutting the heat-dissipating member is prevented to allow the cutting cost to be reduced consequently

As shown in FIG. 4D, an oblique angle is formed on the top edge of the encapsulant 45 around the heat-dissipating member 44 through such as a chamfer grinding process so as to partially expose the edge of the heat-dissipating member 44 having the interface layer 43. In the present embodiment, the encapsulant 45 is grinded until the top corner edge of the heat-dissipating member 44 is exposed.

As shown in FIG. 4E, a removing process is performed so as to remove the encapsulant 45′ located on the interface layer 43. In addition, as the adhesion between the interface layer 43 made of such as a P.I. tape, an epoxy resin or an organic layer and the encapsulant 45 is larger than that between the interface layer 43 and the heat-dissipating member 44, the interface layer 43 and the encapsulant 45′ located on the interface layer 43 can both be removed through the removing process, thereby exposing the top surface of the heat-dissipating member 44. Referring to FIG. 4F, which is a top view of FIG. 4E, heat generated by the semiconductor chip 42 can be dissipated to the outside through the heat-dissipating member 44.

Through the above fabrication method, a semiconductor package structure is obtained, which comprises: a chip carrier 42; a semiconductor chip 41 mounted to and electrically connected to the chip carrier 42; a heat-dissipating member 44 mounted on the semiconductor chip 41; an encapsulant 45 formed on the chip carrier 42 for encapsulating the semiconductor chip 41 and the heat-dissipating member 44, an oblique angle being formed on the top edge of the encapsulant 45 surrounding the heat-dissipating member 44 and the upper surface of the heat-dissipating member 44 being exposed from the encapsulant 45.

### Second Embodiment

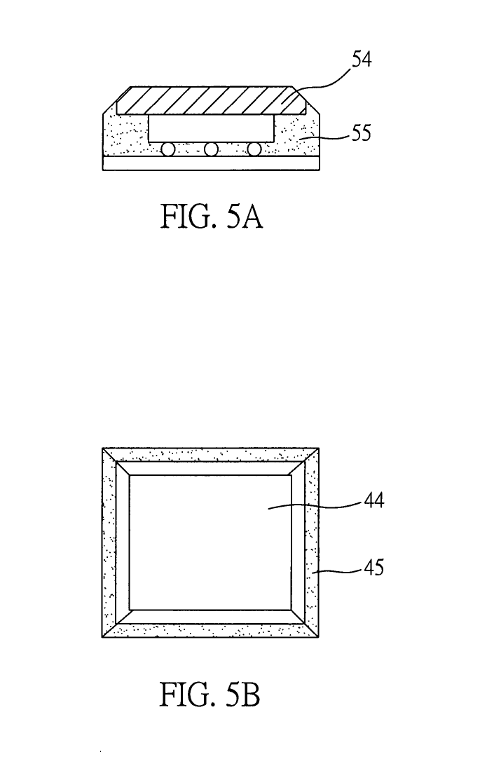

FIG. 5A is a sectional diagram of a heat-dissipating package structure according to a second embodiment of the present invention and FIG. 5B is a top view of the heat-dissipating package structure of FIG. 5A. In the present embodiment, when a chamfer grinding process is performed on the encapsulant 55 so as to form the oblique angle on the top edge of the encapsulant 55, the heat-dissipating member 54 is also grinded through the grinding process for facilitating the removal of the interface layer on the heat-dissipating member and the encapsulant located on the interface layer.

### Third Embodiment

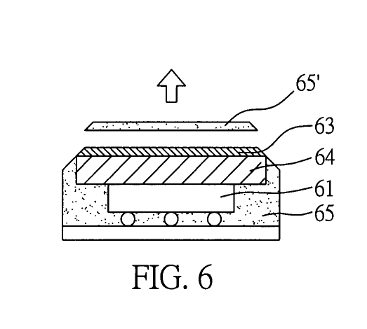

FIG. 6 is a sectional diagram of a heat-dissipating package structure according to a third embodiment of the present invention. In the present embodiment, the interface layer 63 is made of such as Au or Ni. Thus, the adhesion between the interface layer 63 and the heat-dissipating member 64 is larger than that between the interface layer 63 and the encapsulant 65′. Therefore, the encapsulant 65′ located on the interface layer 63 is removed through a removing process while the interface layer 63 remains on the heat-dissipating member 64 and exposed from the encapsulant 65. Thus, heat generated by the semiconductor chip 61 is dissipated to the outside through the heat-dissipating member 64 and the interface layer 63.

### Fourth Embodiment

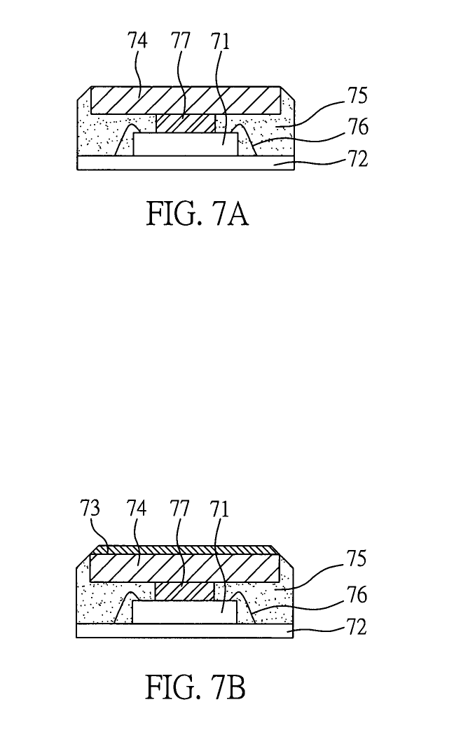

FIGS. 7A and 7B are sectional diagrams showing a heat-dissipating package structure according to a fourth embodiment of the present invention. In the present embodiment, a wire-bonding semiconductor chip 71 is mounted to a chip carrier 72 through its non-active surface, and electrically connected with the chip carrier 72 through a plurality of bonding wires 76. A supporting object 77 such as a scraped chip or a heat-dissipating member is mounted on the active surface of the semiconductor chip 71. Further, a heat-dissipating member 74 having an interface layer 73 is mounted on the supporting object 77. The interface layer 73 may be selected as a P.I. tape, an epoxy resin, an organic layer and so on for making the adhesion between the interface layer 73 and the encapsulant 75 larger than that between the interface layer 73 and the heat-dissipating member 74. Thus, both the interface layer 73 and the encapsulant 75 located on the interface layer 73 can be removed during the removing process so as to expose the heat-dissipating member 74 from the encapsulant, as shown in FIG. 7A. Alternatively, the interface layer 73 can be selected as a metal layer made of such as Au and Ni for making the adhesion between the interface layer 73 and the heat-dissipating member 74 larger than that between the interface layer 73 and the encapsulant 75. Thus, the encapsulant located on the interface layer 73 is removed during the removing process and the interface layer 73 is exposed from the encapsulant, as shown in FIG. 7B.

Therefore, the heat-dissipating package structure and fabrication method thereof mainly comprises the steps of mounting and electrically connecting a semiconductor chip to a chip carrier; mounting a heat-dissipating member having an interface layer on the semiconductor chip; forming an encapsulant that encapsulates the semiconductor chip and the heat-dissipating member having the interface layer on the chip carrier; subsequently, cutting the chip carrier and the encapsulant according to a predetermined package size and forming an oblique angle on the top edge of the encapsulant to partially expose the edge of the heat-dissipating member having the interface layer; and removing the encapsulant located on the interface layer of the heat-dissipating member, thereby forming a heat-dissipating package structure. During the molding process, as there exists a spacing between the interface layer and the top wall of the mold cavity, the formed encapsulant can cover the interface layer, thereby preventing damages to the semiconductor chip pressed by the mold and the problem of flash. Meanwhile, since the cutting line does not pass the heat-dissipating member, the problem of burrs and wearing of cutting tools can be prevented and accordingly the cutting cost can be reduced.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A fabrication method of a heat-dissipating package structure, the fabrication method comprising the steps of:
mounting and electrically connecting at least a semiconductor chip to a chip carrier;
mounting on the semiconductor chip a heat-dissipating member coated with an interface layer;
performing a molding process to form an encapsulant that encapsulates both the semiconductor chip and the heat-dissipating member;
cutting the chip carrier and a circumference of the encapsulant according to a predetermined size of the heat-dissipating package structure;
forming an oblique angle on a top edge of the encapsulant to partially expose an edge of the heat-dissipating member; and
performing a removing process to remove the encapsulant located on the interface layer of the heat-dissipating member.
The fabrication method of claim 1, wherein the chip carrier is one of a BGA substrate and an LGA substrate.

2. The fabrication method of claim 1, wherein the semiconductor chip is a flip-chip semiconductor chip having an active surface electrically connected to the chip carrier through a plurality of conductive bumps.

3. The fabrication method of claim 1, wherein the interface layer is adhered to the encapsulant better than to the heat-dissipating member, making both the interface layer and the encapsulant located on the interface layer removed after the removing process.

4. The fabrication method of claim 3, wherein the interface layer is one selected from the group consisting of a tape comprising Polyimide and adhered to the heat-dissipating member, an epoxy resin coated on the heat-dissipating member, and an organic layer formed on the heat-dissipating member.

5. The fabrication method of claim 1, wherein the interface layer is adhered to the heat-dissipating member better than to the encapsulant, thus, after the encapsulant located on the interface layer is removed through the removing process, the interface layer is exposed from the encapsulant.

6. The fabrication method of claim 5, wherein the interface layer is a metal layer.

7. The fabrication method of claim 1, wherein a chamfer grinding process is performed to form the oblique angle on the top edge of the encapsulant, wherein the encapsulant is ground until the top corner edge of the heat-dissipating member is exposed.

8. The fabrication method of claim 1, wherein a chamfer grinding process is performed to form the oblique angle on the top edge of the encapsulant, wherein the encapuslant and the heat-dissipating member are both ground.

9. The fabrication method of claim 1, wherein the semiconductor chip is a wire-bonding semiconductor chip having an active surface and a corresponding non-active surface, the semiconductor chip being mounted to the chip carrier through its non-active surface and electrically connected to the chip carrier through a plurality of bonding wires.

10. The fabrication method of claim 9, wherein a supporting object is mounted between the active surface of the semiconductor chip and the heat-dissipating member.

11. The fabrication method of claim 10, wherein the supporting object is one of a scraped chip and a heat-dissipating member.

12. The fabrication method of claim 1, wherein the size of the heat-dissipating member is smaller than the predetermined size of the heat-dissipating package structure.

13. A heat-dissipating package structure, comprising:
a chip carrier;
a semiconductor chip mounted on and electrically connected to the chip carrier;
a heat-dissipating member mounted on the semiconductor chip; and
an encapsulant formed on the chip carrier for encapsulating the semiconductor chip and the heat-dissipating member, an oblique angle being formed on the top edge of the encapsulant surrounding the heat-dissipating member and the upper surface of the heat-dissipating member being exposed from the encapsulant.

14. The heat-dissipating package structure of claim 13, wherein the semiconductor chip is a flip-chip semiconductor chip, the active surface thereof being electrically connected to the chip carrier through a plurality of conductive bumps.

15. The heat-dissipating package structure of claim 13, further comprising an interface layer formed on the upper surface of the heat-dissipating member and exposed from the encapsulant.

16. The heat-dissipating package structure of claim 15, wherein the interface layer is a metal layer.

17. The heat-dissipating package structure of claim 13, wherein an oblique angle is formed through a chamfer grinding process and the encapsulant is ground until the top corner edge of the heat-dissipating member is exposed from the encapsulant.

18. The heat-dissipating package structure of claim 13, wherein the oblique angle is formed through a chamfer grinding process and the encapuslant and the heat-dissipating member are both ground.

19. The heat-dissipating package structure of claim 13, wherein the semiconductor chip is a wire-bonding semiconductor chip having an active surface and a corresponding non-active surface, the semiconductor chip being mounted to the chip carrier through its non-active surface and electrically connected to the chip carrier through a plurality of bonding wires.

20. The heat-dissipating package structure of claim 19, wherein a supporting object is mounted between the active surface of the semiconductor chip and the heat-dissipating member having the interface layer.

21. The heat-dissipating package structure of claim 20, wherein the supporting object is one of a scraped chip and a heat-dissipating member.

22. The heat-dissipating package structure of claim 13, wherein the size of the heat-dissipating member is smaller than the predetermined size of the heat-dissipating package structure.
